(19) United States
(12) Patent Application Publication
(10) Pub. No.: US 2013/0334039 A1
(43) Pub. Date: Dec. 19, 2013

(54) OXIDE SINTERED BODY AND SPUTTERING TARGET

(71) Applicants: Hiroshi Goto, Takasago-shi (JP); Yuki Iwasaki, Takasago-shi (JP)

(72) Inventors: Hiroshi Goto, Takasago-shi (JP); Yuki Iwasaki, Takasago-shi (JP)

(73) Assignee: KOBELCO RESEARCH INSTITUTE, INC., Kobe-shi (JP)

(21) Appl. No.: 14/002,491

(22) PCT Filed: Mar. 1, 2012
(86) PCT No.: PCT/JP12/55265

§ 371 Date: Aug. 30, 2013

(30) Foreign Application Priority Data
Mar. 2, 2011 (JP) 2011-045267

(51) Int. Cl. C23C 14/34

(52) U.S. Cl. CPC C23C 14/3407
USPC 204/298.13

(57) ABSTRACT

Provided are an oxide sintered body and a sputtering target which are suitable for use in producing an oxide semiconductor film for display devices and combine high electroconductivity with a high relative density and with which it is possible to form an oxide semiconductor film having a high carrier mobility. In particular, even when used in production by a direct-current sputtering method, the oxide sintered body and the sputtering target are less apt to generate nodules and have excellent direct-current discharge stability which renders long-term stable discharge possible. This oxide sintered body is an oxide sintered body obtained by mixing zinc oxide, tin oxide, and an oxide of at least one metal (M metal) selected from the group consisting of Al, Hf, Ni, Si, Ga, In, and Ta, and sintering the mixture, the oxide sintered body having a Vickers hardness of 400 Hv or higher.

### TECHNICAL FIELD

The present invention relates to an oxide sintered body and a sputtering target used for depositing an oxide semiconductor thin film for a thin film transistor (TFT) by sputtering, which is used for a display device, such as a liquid crystal display or an organic EL display.

### BACKGROUND ART

Amorphous (non-crystalline) oxide semiconductors used in a TFT have a high carrier mobility and a large optical bandgap as compared to generalized amorphous silicon (a-Si), and can be deposited at low temperature. Thus, the amorphous oxide semiconductors are expected to be applied to next-generation display devices required for large size, high resolution, and high-speed driving, as well as resin substrates with a low heat resistance, and the like. In formation of the above oxide semiconductor (film), a sputtering method is preferably used which involves a sputtering target made of the same material as the film. The thin film formed by the sputtering method has excellent in-plane uniformity of the composition or thickness in the direction of the film surface (in the in-plane direction) as compared to thin films formed by ion plating, vacuum evaporation coating, and electron beam evaporation. The sputtering method has an advantage that can form the thin film of the same composition as that of the sputtering target. The sputtering target is normally formed by mixing, sintering, and mechanically processing oxide powders.

The compositions of the oxide semiconductor used in the display device include, for example, In-containing amorphous oxide semiconductors, such as “In—Ga—Zn—O, In—Zn—O, and In—Sn—O (ITO)” (see, for example, Patent Literature 1).

A ZTO-based oxide semiconductor formed by adding Sn to Zn to be made amorphous has been proposed as an oxide semiconductor which can reduce material costs because of the absence of expensive In and which is appropriate for mass production. The ZTO-based oxide semiconductor, however, often causes abnormal discharge during sputtering. For this reason, for example, Patent Literature 2 has proposed a method for suppressing the occurrence of abnormal discharge or cracking during sputtering by controlling a composition of an oxide semiconductor not to contain a tin oxide phase by calcination for a long time. Patent Literature 3 has proposed a method for suppressing the abnormal discharge during sputtering by performing two-stage processes, namely, a temporary powder burning process at a low temperature of 900 to 1300° C., and a main calcination process to increase the density of a ZTO-based sintered body.

### CITATION LIST

### Patent Literature

Patent Literature 1: Japanese Unexamined Patent Publication No. 2008-214697
Patent Literature 2: Japanese Unexamined Patent Publication No. 2007-277075
Patent Literature 3: Japanese Unexamined Patent Publication No. 2008-63214

### SUMMARY OF INVENTION

### Technical Problem

A sputtering target used for manufacturing an oxide semiconductor film for a display device, and an oxide sintered body as the material of the sputtering target are required to have excellent conductivity and high relative density. Further, the oxide semiconductor film obtained by using the sputtering target is required to have high carrier mobility.

In particular, taking into consideration the productivity and manufacturing cost, the sputtering target is required which can be manufactured not by radio-frequency (RF) sputtering, but by DC sputtering adapted for easy deposition at high speed. For example, when depositing a thin film by sputtering using a ZTO-based sputtering target, direct current plasma discharge is normally performed under an atmosphere of a mixed gas of argon gas and oxygen gas. In mass production of thin films by the DC sputtering, the plasma discharge has to be continuously performed for a long time. Thus, the sputtering target is strongly required to have the characteristics (long-term discharge stability) that can stably and continuously perform long-term direct-current discharge from the start of use of the target to the end of use. In particular, as sputtering proceeds using a sputtering target of an oxide containing Sn or In, black attached matter called “nodule” is being formed at an erosion surface (discharge surface) of the sputtering target. The black attached matter is supposed to be made of a lower In oxide or Sn oxide (that is, with lots of defects, for example, having a low density with many oxygen defects), which might cause abnormal discharge in the sputtering. When the sputtering is continued with the nodules formed, defects might be generated in the film by the abnormal discharge, which would generate particles with the nodule itself as a starting point to thereby degrade the quality of display in a display device or to decrease an yield of the display devices.

The technique disclosed in the above Patent Literature 2 is not made by considering the above problem from the standpoint of increasing the density, and is not enough to stably and continuously perform direct-current discharge. Also, the technique disclosed in the above Patent Literature 3 is not made by considering the above problem from the standpoint of improving the conductivity of an oxide sintered body, and is not enough to stably and continuously perform direct-current discharge.

The present invention has been made in view of the above circumstances, and it is an object of the present invention to provide an oxide sintered body and a sputtering target which are suitably used for the production of an oxide semiconductor film for a display device, which have both high conductivity and relative density, and which can deposit an oxide semiconductor film having a high carrier mobility. In particular, the oxide sintered body and the sputtering target are provided which are less likely to generate nodules even in use of the direct current sputtering, and which have excellent stability of the direct-current discharge that can stably produce the long-term discharge.

### Solution to Problem

An oxide sintered body of the invention that can solve the above problems is obtained by mixing zinc oxide, tin oxide, and an oxide of at least one metal (M metal) selected from the group consisting of Al, Hf, Ni, Si, Ga, In, and Ta, and sintering the mixture, the oxide sintered body having a Vickers hardness of 400 Hv or higher.

In a preferred embodiment of the invention, when the Vickers hardness of the oxide sintered body in the thickness direction is approximated by the Gaussian distribution, a distribution coefficient σ of the hardness is 30 or less.

In another preferable embodiment of the invention, when the total amount of metal elements contained in the oxide sintered body is set to 1, M1 metal is at least one metal element selected from the group consisting of Al, Hf, Ni, Si, and Ta of the M metals, and [Zn], [Sn], and [M1 metal] are contents (atomic %) of Zn, Sn, and M1 metal of all the metal elements, respectively, a ratio of [M1 metal] to [Zn]+[Sn]+[M1 metal], a ratio of [Zn] to [Zn]+[Sn], and a ratio of [Sn] to [Zn]+[Sn] respectively satisfy the following formulas:

[M1 metal]/([Zn]+[Sn]+[M1 metal])=0.01 to 0.30;

[Zn]/([Zn]+[Sn])=0.50 to 0.80;

and

[Sn]/([Zn]+[Sn])=0.20 to 0.50.

In another preferable embodiment of the invention, when the total amount of metal elements contained in the oxide sintered body is set to 1, M2 metal is a metal containing at least In or Ga of the M metals, and [Zn], [Sn], and [M2 metal] are contents (atomic %) of Zn, Sn, and M2 metal of all the metal elements, respectively, a ratio of [M2 metal] to [Zn]+[Sn]+[M2 metal], a ratio of [Zn] to [Zn]+[Sn], and a ratio of [Sn] to [Zn]+[Sn] respectively satisfy the following formulas:

[M2 metal]/([Zn]+[Sn]+[M2 metal])=0.10 to 0.30;

[Zn]/([Zn]+=0.50 to 0.80;

and

[Sn]/([Zn]+[Sn])=0.20 to 0.50.

In another preferred embodiment of the invention, the oxide sintered body has a relative density of 90% or more, and a specific resistance of 0.1 Ω·cm or less.

The sputtering target of the invention that can solve the above problems is obtained by using the oxide sintered body described in any one of the above embodiments, in which the sputtering target has a Vickers hardness of 400 Hv or higher.

In another preferred embodiment of the invention, when the Vickers hardness of the sputtering target from a sputtering surface in the thickness direction is approximated by the Gaussian distribution, a distribution coefficient σ of the hardness is 30 or less.

In another preferable embodiment of the invention, when the total amount of metal elements contained in the sputtering target is set to 1, M1 metal is at least one metal element selected from the group consisting of Al, Hf, Ni, Si, and Ta of the M metals, and [Zn], [Sn], and [M1 metal] are contents (atomic %) of Zn, Sn, and M1 metal of all the metal elements, respectively, a ratio of [M1 metal] to [Zn]+[Sn]+[M1 metal], a ratio of [Zn] to [Zn]+[Sn], and a ratio of [Sn] to [Zn]+[Sn] respectively satisfy the following formulas;

[M1 metal]/([Zn]+[Sn]+[M1 metal])=0.01 to 0.30;

[Zn]/([Zn]+[Sn])=0.50 to 0.80;

and

[Sn]/([Zn]+[Sn])=0.20 to 0.50.

In another preferable embodiment of the invention, when the total amount of metal elements contained in the sputtering target is set to 1, M2 metal is a metal containing at least In or Ga of the M metals, and [Zn], [Sn], and [M2 metal] are contents (atomic %) of Zn, Sn, and M2 metal of all the metal elements, respectively, a ratio of [M2 metal] to [Zn]+[Sn]+[M2 metal], a ratio of [Zn] to [Zn]+[Sn], and a ratio of [Sn] to [Zn]+[Sn] respectively satisfy the following formulas:

[M2 metal]/([Zn]+[Sn]+[M2 metal])=0.10 to 0.30;

[Zn]/([Zn]+[Sn])=0.50 to 0.80;

and

[Sn]/([Zn]+[Sn])=0.20 to 0.50.

In another preferred embodiment of the invention, the sputtering target has a relative density of 90% or more, and a specific resistance of 0.1 Ω·cm or less.

### Advantageous Effects of Invention

The present invention can provide the oxide sintered body and sputtering target having a low specific resistance and a high relative density without adding In as a rare metal or even by decreasing the amount of In, which leads to a significant decrease in costs of raw material. Further, the present invention can provide the sputtering target that can continuously exhibit excellent stability of direct-current discharge from the start of use of the sputtering target to the end of use. The use of the sputtering target of the invention can stably and inexpensively deposit the oxide semiconductor film having a high carrier mobility by the direct current sputtering which facilitates the high-speed deposition to thereby improve the productivity of the thin films.

### BRIEF DESCRIPTION OF DRAWINGS

FIG. 1 is a diagram showing basic steps for manufacturing an oxide sintered body and a sputtering target (M metal=Al, Hf, Ni, Si, Ga, and Ta) according to the invention.

FIG. 2 is a diagram showing basic steps for manufacturing an oxide sintered body and a sputtering target (M metal=In) according to the invention.

FIG. 3 is a graph showing the result of a Gaussian distribution (normal distribution) curve of a Vickers hardness in the thickness direction of each of a sputtering target manufactured using an Al-ZTO sintered body of Example 1 (as an example of the invention), and a sputtering target manufactured using a Ta-ZTO sintered body of Comparative Example 1.

FIG. 4 is a graph showing the result of a Gaussian distribution (normal distribution) curve of a Vickers hardness in the thickness direction of each of a sputtering target manufactured using a Ta-ZTO sintered body of Example 2 (as an example of the invention), and the sputtering target manufactured using the Ta-ZTO sintered body of Comparative Example 1.

FIG. 5 is a graph showing the result of a Gaussian distribution (normal distribution) curve of a Vickers hardness in the thickness direction of each of a sputtering target manufactured using an In-ZTO sintered body of Example 3 (as an example of the invention), and the sputtering target manufactured using the Ta-ZTO sintered body of Comparative Example 1.

FIG. 6 is a graph showing the result of a Gaussian distribution (normal distribution) curve of a Vickers hardness in the thickness direction of each of a sputtering target manufactured using a Ga-ZTO sintered body of Example 4 (as an example of the invention), and the sputtering target manufactured using the Ta-ZTO sintered body of Comparative Example 1.

### DESCRIPTION OF EMBODIMENTS

The inventors have studied about oxide (ZTO) semiconductors containing Zn and Sn so as to provide an oxide sintered body for a sputtering target that can suppress the occurrence of nodules even in use of direct current sputtering, and which can produce the long-term stable discharge from the start of use of the sputtering target to the end of use, in addition to having high conductivity and high relative density.

As a result, the oxide sintered body (further including the sputtering target) has a correlation between the hardness and the discharge stability. As the oxide sintered body becomes harder, the sintered body can more stably produce the discharge to thereby effectively suppress the occurrence of nodules. Such an effect is found to be promoted by decreasing variations in hardness distribution in the thickness direction as much as possible. For this reason, the inventors have further studied about techniques that can control the hardness of the oxide sintered body, and found out the following. Each oxide of metal elements (Zn, Sn) contained in ZTO, and an oxide of at least one metal element (M metal) selected from the group consisting of Al, Hf, Ni, Si, Ga, In, and Ta are mixed and sintered to thereby produce a M metal-containing ZTO sintered body. The thus-obtained sintered body is used to manufacture the sputtering target by a manufacturing method under recommended conditioned to be described later. The oxide sintered body and the sputtering target have an improved Vickers hardness. Preferably, variations in Vickers hardness in the thickness direction are reduced, so that abnormal discharge in deposition is suppressed, which can stably and continuously obtain the direct-current discharge over time. A TFT having an oxide semiconductor thin film deposited using the above sputtering target is found to have very high characteristics, for example, a carrier density of 15 cm²/Vs or more. In order to obtain such a M-metal containing ZTO sintered body, preferably, the following processes should be performed. That is, the mixed powder for use is prepared by appropriately controlling the ratio of the total amount of the M metals to all metal elements (Zn+Sn+M metals), and the ratio of Zn or Sn to the total amount of Zn and Sn. Then, the mixed powder is sintered under predetermined sintering conditions (preferably, under a non-reducing atmosphere, at a temperature of 1350 to 1650° C. for 5 hours or more). In this way, the invention has been made based on the above findings.

The invention employs a mechanism for controlling the hardness of an oxide sintered body (and further sputtering target) (and further for controlling the hardness distribution in the thickness direction) to suppress the occurrence of nodules upon sputtering to thereby produce the stable direct-current discharge. The mechanism is not specifically definite, but is based on the fact that, the features of an internal structure of the oxide sintered body, including density, internal defects, distribution of voids, density of voids, the composition, and distribution of the composition of the oxide sintered body have an influence on the hardness of the oxide sintered body. The hardness (further, the hardness distribution) of the oxide sintered body has a good correlation with the quality of sputtering.

Now, the components of the oxide sintered body in the invention will be described in detail.

The oxide sintered body of the invention is obtained by mixing zinc oxide, tin oxide, and an oxide of at least one metal (M metal) selected from the group consisting of Al, Hf, Ni, Si, Ga, In, and Ta, and sintering the mixture, the oxide sintered body having a Vickers hardness of 400 Hv or higher.

The oxide sintered body of the invention has a Vickers hardness of 400 Hv or higher. As a result, the sputtering target formed using the oxide sintered body has a Vickers hardness of 400 Hv or higher, which improves the direct-current discharge in sputtering. The oxide sintered body having a higher Vickers hardness has better quality. The Vickers hardness is preferably 420 Hv or higher, and more preferably 430 Hv or higher. The upper limit of the Vickers hardness is not specifically limited from the standpoint of improvement of the direct-current discharge, but is preferably controlled in such an appropriate range that obtains a high-density sintered body without defects, including cracks. The above Vickers hardness is a value measured in one position of the cross section of the oxide sintered body taken in the position of t/2 (t: thickness).

Further, when the Vickers hardness of the oxide sintered body in the thickness direction is approximated by the Gaussian distribution (normal distribution), a distribution coefficient σ of the hardness is preferably controlled to be 30 or less. The oxide sintered body in which variations in Vickers hardness between specimens thereof is greatly reduced under control has an improved direct-current discharge in sputtering. The oxide sintered body having a smaller distribution coefficient has better quality. The distribution coefficient of the sintered body is preferably 25 or less.

Specifically, 10 pieces of the above oxide sintered body each are cut in a plurality of positions in the thickness direction (t) (t/4 position, t/2 position, and 3×t/4 position) to expose respective surfaces. Then, a Vickers hardness of each position of the exposed surface (position of the cross-sectional surface) is measured. The same procedure is performed on 10 pieces of the oxide sintered body. The Vickers hardness of each piece is approximated by the Gaussian distribution represented by the following formula f(x) to determine a distribution coefficient σ of the Vickers hardness in the thickness direction.

$$f ( x ) = \frac{1}{\sqrt{2 π} G} exp \{ - \frac{{( x - μ )}^{2}}{2 {σ}^{2}} \} \qquad ( 1 )$$

where μ is an average of Vickers hardnesses.

Next, the M metal used in the invention will be described below. The above M metal is at least one kind of metal (M metal) selected from the group consisting of Al, Hf, Ni, Si, Ga, In, and Ta. The M metal is an element contributing to improvement of the Vickers hardness of each of the oxide sintered body and the sputtering target. As a result, the direct-current discharge is improved. The above M metal is also an element largely contributing to the improvement of the relative density and the reduction of the specific resistance of a Zn—Sn—O (ZTO) sintered body consisting of only Zn and Sn. This also results in improvement of the direct-current discharge. Further, the above M metal is an element useful for improvement of the properties of the film deposited by sputtering. The single M metal may be used, or a combination of two or more M metals may be used.

The preferable ratio of metal elements in all metals contained in the oxide sintered body of the invention varies depending on the type of the M metal as will be described in detail below. That is, the lower limit of the preferable ratio of the M metal to all metal elements differs depending on whether the M metal selected from the group consisting of Al, Hf, Ni, Si, Ga, In, and Ta contains at least In or Ga, or not. In the former case, the lower limit of the preferable ratio is slightly larger than that in the latter case. Now, the preferable ratio in each case will be described in detail below.

(A) in the Case where the M Metal is at Least One Kind of Metal (M1 Metal) Selected from the Group Consisting of Al, Hf, Ni, Si, and Ta:

That is, the above case is a case where the above M metal does not contain In and Ga. Such a M metal is called “M1 metal”. When the total amount of metal elements contained in the oxide sintered body is set to 1, and [Zn], [Sn], and [M1 metal] are contents (atomic %) of Zn, Sn, and M1 of all the metal elements, respectively, a ratio of [M1 metal] to [Zn]+[Sn]+[M1 metal], a ratio of [Zn] to [Zn]+[Sn], and a ratio of [Sn] to [Zn]+[Sn] respectively satisfy the following formulas. The term “[M1 metal] content” means the amount of M1 metal in use of the single M1 metal, or the total amounts of two or more kinds of M1 metals in use of the two or more kinds of the M1 metals.

[M1 metal]/([Zn]+[Sn]+[M1 metal])=0.01 to 0.30;

[Zn]/([Zn]+[Sn])=0.50 to 0.80;

and

[Sn]/([Zn]+[Sn])=0.20 to 0.50.

The ratio of [M1 metal] to [Zn]+[Sn]+[M1 metal] (hereinafter simply abbreviated to as a “M1 metal ratio”) is preferably in a range of 0.01 to 0.30. For the M1 metal ratio of less than 0.01, an effect of the addition of the M metal is not effectively exhibited. In using the sintered body for the sputtering target, the direct-current discharge stability is degraded, the mobility of a thin film formed is decreased, and the reliability of the TFT is also reduced. In contrast, for the M1 metal ratio exceeding 0.30, the density of the sintered body cannot be increased to 90% or more, and also the specific resistance thereof is increased, which does not stabilize the direct-current plasma discharge, thus easily causing the abnormal discharge. Moreover, the switching characteristics of the TFT are degraded (including increase in off-state current, variations in threshold voltage, and reduction in subthreshold characteristic, and the like), so that the reliability of the TFT is reduced. Thus, the thin film deposited cannot achieve the performance required for application to the display device and the like. The M1 metal ratio is more preferably not less than 0.01 and not more than 0.10.

The ratio of [Zn] to ([Zn]+[Sn]) (hereinafter simply abbreviated as a “Zn ratio”) is preferably in a range of 0.50 to 0.80. For the Zn ratio of less than 0.50, the micro-workability of the thin film formed by the sputtering is degraded, which is likely to cause an etching residue. In contrast, for the Zn ratio exceeding 0.80, the deposited thin film reduces the resistance to chemicals, and thus cannot achieve the high-accuracy processing because of the high dissolution rate of components of the thin film into an acid in the microfabrication. The Zn ratio is more preferably not less than 0.55 and not more than 0.70.

The ratio of [Sn] to ([Zn]+[Sn]) (hereinafter simply abbreviated as a “Sn ratio”) is preferably in a range of 0.20 to 0.50. For the Sn ratio of less than 0.20, the thin film deposited by sputtering reduces the resistance to chemicals, and thus cannot achieve the high-accuracy processing because of the high dissolution rate of components of the thin film into an acid in the microfabrication. In contrast, for the [Sn] ratio exceeding 0.50, the micro-workability of the thin film formed by the sputtering is degraded, which is likely to cause an etching residue. Thus, the [Sn] ratio is more preferably not less than 0.25 and not more than 0.40

(B) in the Case where the M Metal Contains at Least In or Ga

The metal containing at least one of In and Ga of the M metals is referred to as a “M2 metal”. When the total amount of metal elements contained in the oxide sintered body is set to 1, and [Zn], [Sn], and [M2 metal] are contents (atomic %) of Zn, Sn, and M2 metal of all the metal elements, respectively, a ratio of [M2 metal] to [Zn]+[Sn]+[M2 metal], a ratio of [Zn] to [Zn]+[Sn], and a ratio of [Sn] to [Zn]+[Sn] respectively satisfy the following formulas. The term “[M2 metal] content” means the amount of M2 metal in use of the single M2 metal, or the total amounts of two or more kinds of M2 metals in use of the two or more kinds of the M2 metals.

[M2 metal]/([Zn]+[Sn]+[M2 metal])=0.10 to 0.30;

[Zn]/([Zn]+[Sn])=0.50 to 0.80;

and

[Sn]/([Zn]+[Sn])=0.20 to 0.50.

The reasons for setting the Zn ratio and Sn ratio, and the preferable ranges thereof are the same as those described above about the case (A).

The ratio of [M2 metal] to [Zn]+[Sn]+[M2 metal] (hereinafter simply abbreviated to as a “M2 metal ratio”) is preferably in a range of 0.01 to 0.30. This setting increases an on-state current of a thin film transistor to thereby improve the subthreshold characteristics. As a result, a carrier mobility of the thin film is increased to improve the performance of the display device. For the M2 metal ratio of less than 0.10, the effect of the addition of the M2 metal is not effectively exhibited. In use of the oxide sintered body for the sputtering target, the direct-current discharge stability is degraded, the mobility of the thin film formed, and the reliability of the TFT are also reduced. In contrast, when the above M2 metal contains at least Ga without containing In, for the M2 metal ratio exceeding 0.30, the density of the sintered body cannot be increased to 90% or more, and further the specific resistance thereof is increased, which does not stabilize the direct current plasma discharge, thus easily causing the abnormal discharge. The off-state current of the TFT is increased to cause damage on the characteristics of the semiconductor. The M2 metal ratio is more preferably not less than 0.15 and not more than 0.25.

The oxide sintered body of the invention preferably satisfies the following features: the relative density of 90% or more, and the specific resistance of 0.1 Ω·cm or less.

### (Relative Density of 90% or More)

The oxide sintered body of the invention has a very high relative density, preferably of 90% or more, and more preferably of 95% or more. The high relative density can prevent the occurrence of cracking or nodules during sputtering, and can advantageously constantly and continuously keep the discharge stable from the start of use of the sputtering target to the end of use.

(Specific Resistance of 0.1 Ω·cm or less)

The oxide sintered body of the invention has a small specific resistance, preferably, of 0.1 Ω·cm or less, and more preferably, of 0.05 Ω·cm or less. This setting allows the deposition by the DC sputtering method of plasma discharge using a DC power supply. As a result, the physical vapor deposition (sputtering) using a sputtering target can be effectively performed on a production line of the display devices.

Next, a method for manufacturing the oxide sintered body according to the invention will be described below.

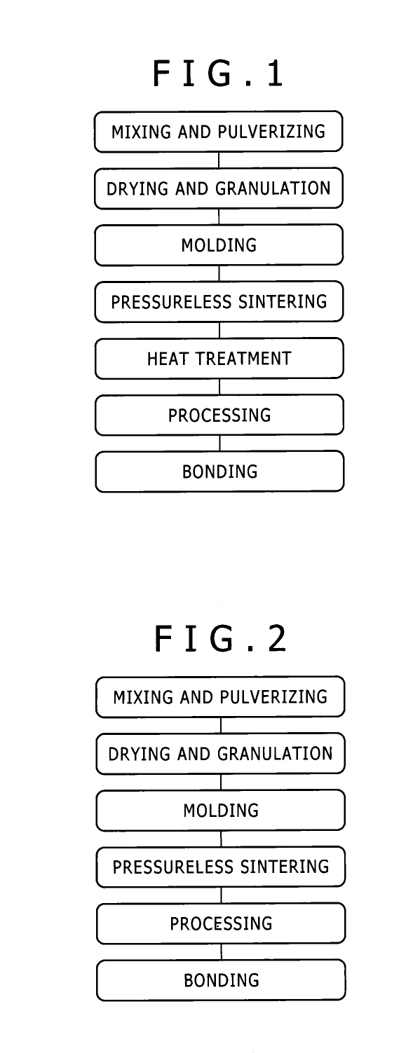

The oxide sintered body of the invention is obtained by mixing zinc oxide; tin oxide; and an oxide of at least one metal (M metal) selected from the group consisting of Al, Hf, Ni, Si, Ga, In, and Ta, and sintering the mixture. Basic steps from the powders of raw material up to the sputtering target are shown in FIGS. 1 and 2. FIG. 1 illustrates a flow of manufacturing steps of the oxide sintered body when the M metal is a metal other than In, that is, M metal=Al, Hf, Ni, Si, Ga, and/or Ta. FIG. 2 illustrates a flow of manufacturing steps of the oxide sintered body in the case of M metal=In. By comparison between the steps of FIG. 1 and FIG. 2, the procedure shown in FIG. 1 involves a heat treatment after pressureless sintering, whereas the procedure shown in FIG. 2 does not involve the heat treatment after the pressureless sintering, which is only a difference between FIGS. 1 and 2. The invention covers an embodiment which uses two or more metal elements as the M metal. For example, when two metals, In and Al are used as the M metal, the oxide sintered body has only to be manufactured based on the procedure shown in FIG. 2.

Referring to FIG. 1, in the case of M metal=Al, Hf, Ni, Si, Ga, and/or Ta, the manufacturing steps of the oxide sintered body will be described below. FIG. 1 illustrates the basic steps in which the oxide sintered body obtained by mixing and pulverizing, drying and granulation, molding, pressureless sintering, and heat treatment of respective oxide powders in that order is further processed and bonded to produce a sputtering target. In the invention, only the sintering conditions and the heat treatment conditions thereafter in the above steps are appropriately controlled as will be described in detail later, and other steps are not limited to specific ones and can be performed by normal processes appropriately selected. Now, each step will be described below, but the invention is not limited thereto. In the invention, preferably, the above conditions are appropriately controlled depending on the kind of the M metal and the like.

First, zinc oxide powder, tin oxide powder, and oxide M metal powder are blended at a predetermined ratio, mixed, and pulverized. The purity of each of the raw material powders used is preferably about 99.99% or more. Even the presence of a small amount of impurity element might degrade the semiconductor properties of the oxide semiconductor film. The blending ratio of the raw material powders is preferably controlled such that the ratio of each of Zn, Sn, and M metal is within the above corresponding range.

The mixing and pulverizing processes are preferably performed using a pot mill, into which the raw material powders are charged with water. Balls and beads used in the steps are preferably formed of, for example, nylon, alumina, zirconia, and the like.

Then, the mixed powders obtained in the above steps are dried and granulated, and thereafter molded. In molding, preferably the powders after the drying and granulation are charged into a die having a predetermined size, preformed by die pressing, and then molded by CIP (cold isostatic press) or the like. In order to increase the relative density of the sintered body, the molding pressure in the preforming step is preferably controlled to about 0.2 tonf/cm² or more, and the pressure in the molding is preferably controlled to about 1.2 tonf/cm² or more.

Then, the thus-obtained molded body is sintered under normal pressure. In the invention, the sintering is preferably performed at a sintering temperature of about 1350 to 1650° C. for a holding time of about 5 hours or more. Thus, a large amount of Zn₂SnO₄ contributing to the improvement of the relative density is formed in the sintered body, which results in a high relative density of the sputtering target, and thus improves the discharge stability. As the sintering temperature becomes higher, the relative density of the sintered body tends to be improved, and also the molded body can be sintered for a shorter time, which is preferable. However, as the sintering temperature is excessively high, the sintered body is apt to be decomposed. Accordingly, the sintering conditions are preferably within the above ranges. The sintering is more preferably performed at a sintering temperature of about 1450 to 1600° C. for a holding time of about 8 hours or more. The sintering atmosphere is preferably a non-reducing atmosphere, and for example, is preferably controlled by introducing oxygen gas into a furnace.

Then, the thus-obtained sintered body is subjected to heat treatment to thereby produce the oxide sintered body of the invention. In order to produce the sintered body that can perform the plasma discharge by a direct current power supply in the invention, the heat treatment is preferably controlled at a heat treatment temperature of about 1000° C. or more for a holding time of about 8 hours or more. The above treatment decreases the specific resistance, for example, from about 100 Ω·cm (before the heat treatment) to 0.1 Ω·cm (after the heat treatment). More preferably, the heat treatment is performed at a heat treatment temperature of about 1100° C. or more for a holding time of about 10 hours or more. The heat treatment atmosphere is preferably a reducing atmosphere, and for example, is preferably controlled by introducing oxygen gas into a furnace. Specifically, the atmosphere is preferably controlled appropriately depending on the kind of the M metal and the like.

After obtaining the oxide sintered body in the way described above, the steps of processing and bonding can be performed by normal methods to produce the sputtering target of the invention. The thus-obtained sputtering target also has a Vickers hardness of 400 Hv or higher, like the above oxide sintered body, and preferably a distribution coefficient of the Vickers hardness in the thickness direction of 30 or less. Further, the Zn ratio, the Sn ratio, the M1 metal ratio, and the M2 metal ratio of the sputtering target also satisfy the preferable ratios of the oxide sintered body as described above. The sputtering target also has the very good relative density and specific resistance like the oxide sintered body, and preferably has a relative density of about 90% or more, and a specific resistance of about 0.1 Ω·cm or less.

Referring to FIG. 2, in the case of M metal=In (that is, when the M metal contains at least In), manufacturing steps of the oxide sintered body will be described below. As mentioned above, in use of the M metal containing at least In, the above-mentioned heat treatment after the pressureless sintering shown in the above-mentioned FIG. 1 is not performed. The phrase “heat treatment after the sintering is not performed in use of the metal containing In” means that the specific resistance of the sintered body can be decreased without the heat treatment, which eliminates the necessity of the heat treatment (that is, provision of the heat treatment is worthless from the viewpoint of the productivity). The phrase does not mean that the heat treatment after the sintering is positively excluded. Even the heat treatment after the pressureless sintering does not adversely affect the characteristics, including the specific resistance. Thus, the heat treatment after the sintering may be performed without taking into consideration the productivity. The thus-obtained sintered body can fall within the scope of claims of the present invention. Except for the above step, the procedure shown in FIG. 2 is the same as that shown in FIG. 1. The detailed description of other steps except for the above step can be understood by the description about FIG. 1.

The present application claims the benefit of priority to Japanese Patent Application No. 2011-045267 filed on Mar. 2, 2011. The disclosure of Japanese Patent Application No. 2011-045267 filed on Mar. 2, 2011 including the specification, drawings and abstract is incorporated herein by reference in its entirety.

### EXAMPLES

Now, the present invention will be more specifically described with reference to examples below. However, the invention is not limited to the following examples, and various changes can be appropriately made to the examples so as to comply with the spirit of the invention, and any one of the examples can fall within the technical scope of the invention.

### Example 1

Zinc oxide powder (JIS1) having a purity of 99.99%, tin oxide powder having a purity of 99.99%, and aluminum oxide powder having a purity of 99.99% were blended at the ratio of [Zn] [Sn]:[Al]=73.9:24.6:1.5, and mixed by a nylon ball mill for 20 hours. For reference, Table 1 shows the Zn ratio and the Sn ratio. The Al ratio was 0.015. Then, the mixed powders obtained in the above process were dried and granulated, preformed at a molding pressure of 0.5 tonf/cm² by the die press, and then mainly molded at a molding pressure of 3 tonf/cm² by the CIP.

As shown in Table 1, the thus-obtained molded body was sintered while being held at 1500° C. under normal pressure for 7 hours. At this time, the sintering was performed under the oxygen atmosphere with oxygen gas introduced into a sintering furnace. Then, the sintered body was put in a heat treatment furnace, and subjected to heat treatment at 1200° C. for 10 hours. The heat treatment was performed under the reducing atmosphere with nitrogen gas introduced into the heat treatment furnace.

Then, the relative density of the thus-obtained oxide sintered body of Example 1 was measured by Archimedes' method to be 90% or more. Then, a specific resistance of the oxide sintered body was measured by a four-probe method to be 0.1 Ω·cm or less. Thus, good results were obtained.

Further, the above oxide sintered body was processed into a piece having φ4 inch×5 mmt, which was bonded to a backing plate to produce the sputtering target. The thus-obtained sputtering target was mounted to sputtering equipment, and then an oxide semiconductor film was formed over a glass substrate (having a size of 100 mm×100 mm×0.50 mm) by DC (direct current) magnetron sputtering. The sputtering conditions were as follows: DC sputtering power of 150 W, Ar/0.1 vol. % O₂ atmosphere, and pressure of 0.8 mTorr. As a result, the occurrence of the abnormal discharge (arcing) was not observed from the start of use of the sputtering target to the end of use, so that the stable discharge was confirmed.

The Vickers hardness of a sputtering surface of the above sputtering target was measured to be 438 Hv, which satisfied the range (400 Hv or higher) of the invention. Further, a distribution coefficient of a Vickers hardness of the sputtering target was measured in the depth direction from the sputtering surface based on the above-mentioned method, whereby the measured values satisfied the preferred range (30 or less) of the invention, resulting in less variations in measured values (see Table 1).

A thin film deposited under the above sputtering conditions was used to make a thin film transistor with a channel length 10 μm and a channel width 100 μm. Then, the carrier mobility of the transistor was measured. As a result, the high carrier mobility of 15 cm²/Vs or more was obtained.

### Example 2

Zinc oxide powder (JIS1) having a purity of 99.99%, tin oxide powder having a purity of 99.99%, and tantalum oxide powder having a purity of 99.99% were blended at the ratio of [Zn] [Sn]:[Ta]=73.9:24.6:1.5. The mixed powder was sintered at 1550° C. for 5 hours, and subjected to heat treatment at 1150° C. for 14 hours. Except for the above points, the same processes as those in Example 1 described above were performed in Example 2, which produced the oxide sintered body of Example 2 (Ta ratio=0.015).

The relative density and specific resistance of the thus-obtained oxide sintered body of Example 2 were measured in the same way as in the above Example 1. As a result, the relative density of the oxide sintered body was 90% or more, and the specific resistance thereof was 0.1 Ω·cm or less, so that good results were obtained.

Then, the above oxide sintered body was used to perform the DC (direct current) magnetron sputtering in the same way as in the above Example 1. As a result, the occurrence of the abnormal discharge (arcing) was not observed, and the stable discharge was confirmed.

A Vickers hardness of the above sputtering target was measured in the same way as in Example 1 to be 441 Hv, which satisfied the range of the invention (400 Hv or higher). Further, a distribution coefficient of a Vickers hardness of the sputtering target in the depth direction from a discharge surface of the sputtering target was measured based on the above-mentioned method, whereby the measured values satisfied the preferred range (30 or less) of the invention, resulting in less variations in measured values (see Table 1).

The carrier mobility was measured using a thin film deposited under the above sputtering conditions, in the same way as in the above Example 1. As a result, the high carrier mobility of 15 cm²/Vs or more was obtained.

### Example 3

Zinc oxide powder (JIS1) having a purity of 99.99%, tin oxide powder having a purity of 99.99%, and indium oxide powder having a purity of 99.99% were blended at the ratio of [Zn] [Sn] [In]=45.0:45.0:10.0. The mixed powder was sintered at 1550° C. for 5 hours (without the heat treatment). Except for the above points, the same processes as those in Example 1 described above were performed in Example 3, which produced the oxide sintered body of Example 3 (In ratio=0.10).

The relative density and specific resistance of the thus-obtained oxide sintered body of Example 3 were measured in the same way as in the above Example 1. As a result, the relative density of the oxide sintered body was 90% or more, and the specific resistance thereof was 0.1 Ω·cm or less, so that good results were obtained.

Then, the above oxide sintered body was used to perform the DC (direct current) magnetron sputtering in the same way as in the above Example 1. As a result, the occurrence of the abnormal discharge (arcing) was not observed, and the stable discharge was confirmed.

A Vickers hardness of the above sputtering target was measured in the same way as in Example 1 to be 441 Hv, which satisfied the range of the invention (400 Hv or higher). Further, a distribution coefficient of a Vickers hardness of the sputtering target in the depth direction from a discharge surface of the sputtering was measured based on the above-mentioned method, whereby the measured values satisfied the preferable range (30 or less) of the invention, resulting in less variations in measured values (see Table 1).

The carrier mobility was measured using a thin film deposited under the above sputtering conditions in the same way as in the above Example 1. As a result, the high carrier mobility of 15 cm²/Vs or more was obtained.

### Example 4

Zinc oxide powder (JIS1) having a purity of 99.99%, tin oxide powder having a purity of 99.99%, and gallium oxide powder having a purity of 99.99% were blended at the ratio of [Zn] [Sn] [Ga]=60.0:30.0:10.0. The mixed powder was sintered at 1600° C. for 8 hours, and subjected to heat treatment at 1200° C. for 16 hours. Except for the above points, the same processes as those in Example 1 described above were performed in Example 4, which produced the oxide sintered body of Example 4 (Ga ratio=0.10).

The relative density and specific resistance of the thus-obtained oxide sintered body of Example 4 were measured in the same way as in the above Example 1. As a result, the relative density of the oxide sintered body was 90% or more, and the specific resistance thereof was 0.1 Ω·cm or less, so that good results were obtained.

Then, the above oxide sintered body was used to perform the DC (direct current) magnetron sputtering in the same way as in the above Example 1. As a result, the occurrence of the abnormal discharge (arcing) was not observed, and the stable discharge was confirmed.

A Vickers hardness of the above sputtering target was measured in the same way as in the Example 1 to be 461 Hv, which satisfied the range of the invention (400 Hv or higher). Further, a distribution coefficient of a Vickers hardness of the sputtering target in the depth direction from a discharge surface of the sputtering was measured based on the above-mentioned method, whereby the measured values satisfied the preferable range (30 or less) of the invention, resulting in less variations in measured values (see Table 1).

The carrier mobility was measured using a thin film deposited under the above sputtering conditions in the same way as in the above Example 1. As a result, the high carrier mobility of 15 cm²/Vs or more was obtained.

### Comparative Example 1

Comparative Example 1 produced the oxide sintered body in the same way as in the above Example 2 except that a molded body was sintered while being kept at 1300° C. for 5 hours in a furnace and then subjected to the heat treatment at 1200° C. for 10 hours.

The relative density and specific resistance of the thus-obtained oxide sintered body of Comparative Example 1 were measured in the same way as in the above Example 1. Since the sintering temperature was lower than the lower limit (1350° C.) recommended by the invention, the relative density of the oxide sintered body was less than 90%, and the specific resistance thereof exceeded 0.1 Ω·cm.

Then, the above oxide sintered body was used to perform the DC (direct current) magnetron sputtering in the same way as in the above Example 1. As a result, abnormal discharge irregularly occurred. When the sputtering surface was visually observed after the end of the discharge, rough areas including nodules were observed. Further, when the sputtering surface was observed with an optical microscope after the end of the discharge, defects generated by abnormal discharge on the thin film side were observed.

A Vickers hardness of the above sputtering target was measured in the same way as in the Example 1 to be 358 Hv, which was below the range of the invention (400 Hv or higher). Further, a distribution coefficient of a Vickers hardness of the sputtering target in the depth direction from a discharge surface of the sputtering was measured based on the above-mentioned method, whereby the measured values exceeded the preferable range (30 or less) of the invention, resulting in large variations in measured values (see Table 1).

TABLE 1

| | | | | Vickers | |
|---|---|---|---|---|---|
| | | | | hardness | Distribution |
| | | Zn/(Zn + Sn) | Sn/(Zn + Sn) | (Hv) | coefficient |
| Example 1 | 1.5 at % Al-ZTO | 0.750 | 0.250 | 438 | 29 |
| | (Sintering | | | | |
| | temperature | | | | |
| | 1500° C., 7 hr) | | | | |
| Example 2 | 1.5 at % Ta-ZTO | 0.750 | 0.250 | 441 | 12 |
| | (Sintering | | | | |
| | temperature | | | | |
| | 1550° C., 5 hr) | | | | |
| Example 3 | 10 at % In-ZTO | 0.5 | 0.5 | 434 | 14 |
| | (Sintering | | | | |
| | temperature | | | | |
| | 1550° C., 5 hr) | | | | |
| Example 4 | 10 at % Ga-ZTO | 0.667 | 0.333 | 461 | 22 |
| | (Sintering | | | | |
| | temperature | | | | |
| | 1600° C., 8 hr) | | | | |
| Comparative | Ref) | 0.750 | 0.250 | 358 | 68 |
| example 1 | 1.5 at % Ta-ZTO | | | | |
| | (Sintering | | | | |
| | temperature | | | | |
| | 1300° C., 5 hr) | | | | |

The carrier mobility was measured using a thin film deposited under the above sputtering conditions in the same way as in the above Example 1. As a result, the carrier mobility was measured to be 3.0 cm²/Vs, which was low.

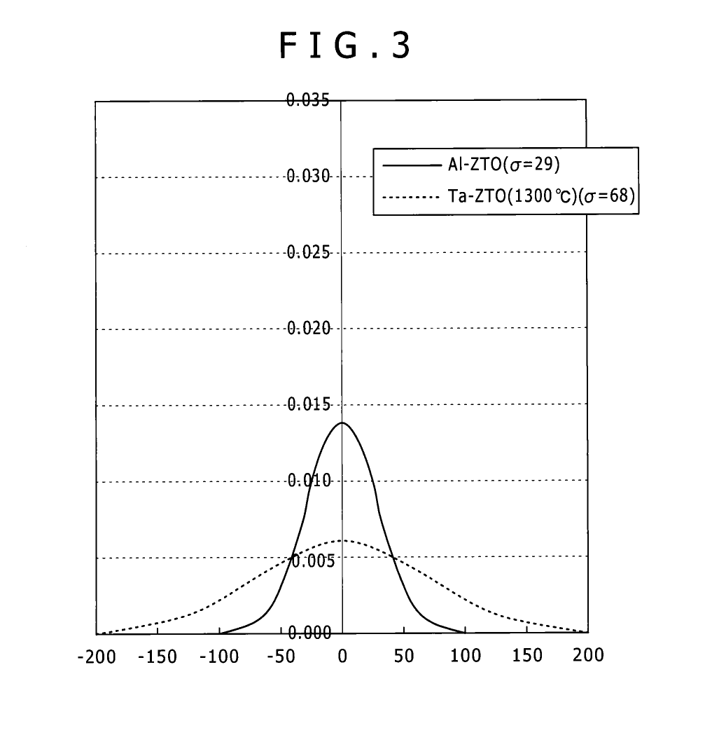

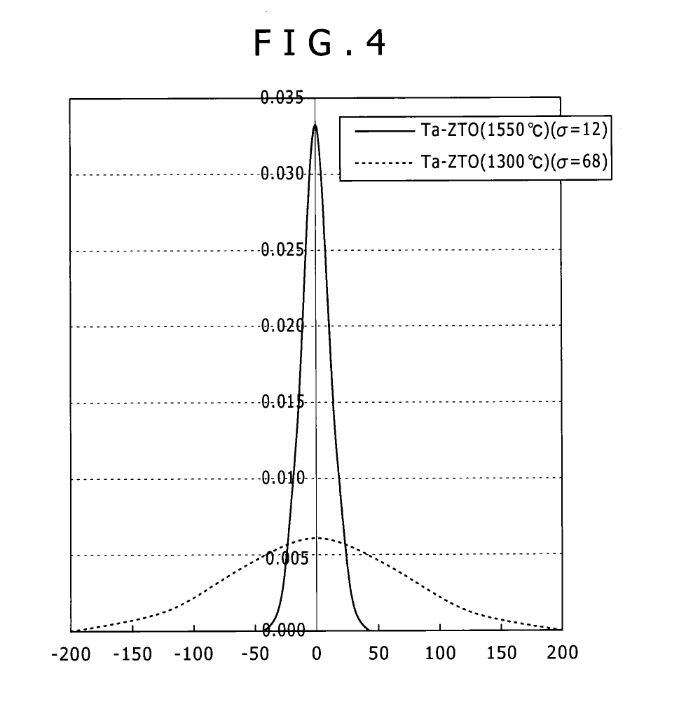

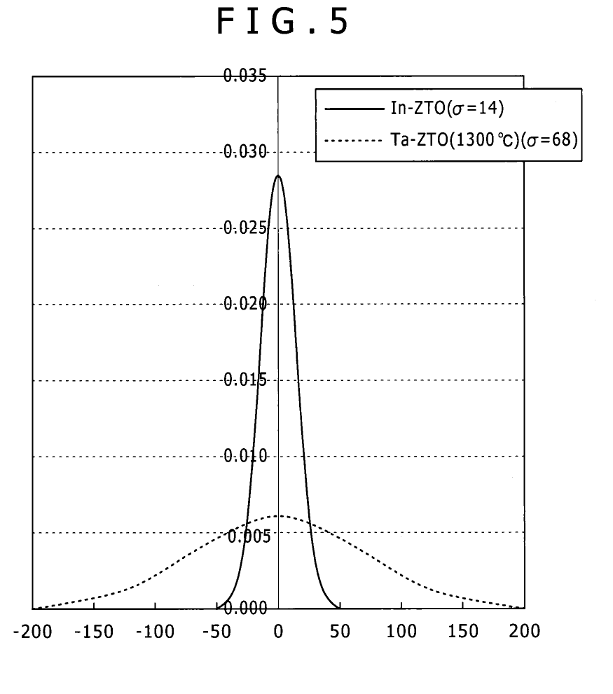

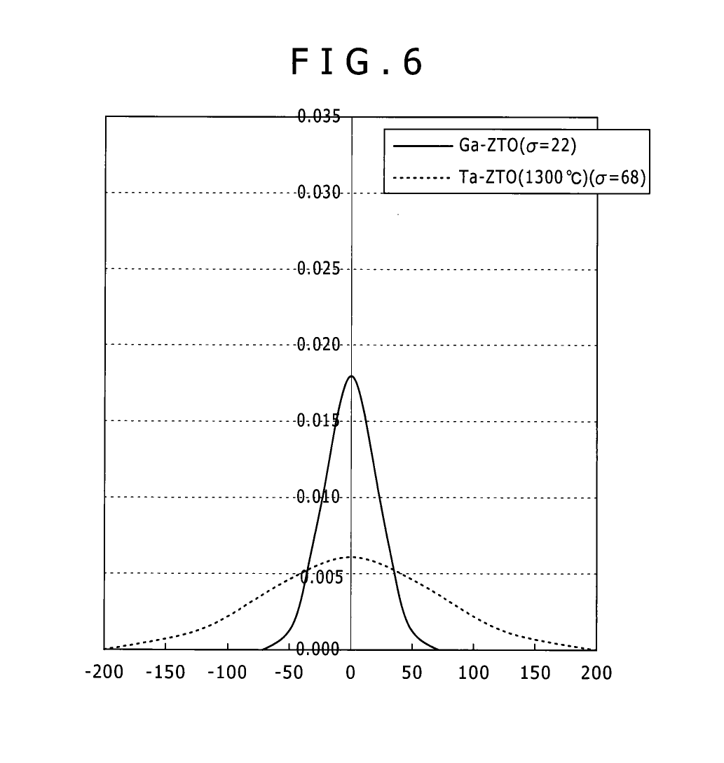

For reference, FIGS. 3 to 6 show the results of the Gaussian distributions (normal distributions) of the Vickers hardnesses of the sputtering targets of Examples 1 to 4. Each diagram also shows the result of the sputtering target of Comparative Example 1 for comparison. As can be seen from the figures, the invention can provide the sputtering target that has a high Vickers hardness and which suppresses variations in Vickers hardness as compared to the comparative example.

As can be seen from the above results of the experiments, the oxide sintered body of each of Examples 1 to 5 contains the M metal defined by the invention, reduces its distribution coefficient of a specific resistance to 0.02 or less, and satisfies the preferred requirements of the invention for the composition ratio of metals contained in the oxide sintered body. The sputtering targets obtained by using the above oxide sintered bodies have the high relative density and the low specific resistance, and can produce the long-term stable discharge even after being manufactured by the direct current sputtering. The thin film obtained by using the above sputtering target has the high carrier mobility, and thus is very useful as an oxide semiconductor thin film.

1. An oxide sintered body obtained by mixing zinc oxide, tin oxide, and an oxide of at least one metal (M metal) selected from the group consisting of Al, Hf, Ni, Si, Ga, In, and Ta, to form a mixture, and sintering the mixture,
wherein the oxide sintered body has a Vickers hardness of 400 Hv or higher.

2. The oxide sintered body according to claim 1, wherein, when the Vickers hardness of the oxide sintered body in a thickness direction is approximated by Gaussian distribution, a distribution coefficient σ of the hardness is 30 or less.

3. The oxide sintered body according to claim 1, wherein, when a total amount of metal elements contained in the oxide sintered body is set to 1:
M1 metal is at least one metal element selected from the group consisting of Al, Hf, Ni, Si, and Ta of the M metals;
[Zn], [Sn], and [M1 metal] are contents (atomic %) of Zn, Sn, and M1 metal of all the metal elements, respectively; and
a ratio of [M1 metal] to [Zn]+[Sn]+[M1 metal], a ratio of [Zn] to [Zn]+[Sn], and a ratio of [Sn] to [Zn]+[Sn] respectively satisfy the following formulas:
[M1 metal]/([Zn]+[Sn]+[M1 metal])=0.01 to 0.30;
[Zn]/([Zn]+[Sn])=0.50 to 0.80;
and
[Sn]/([Zn]+[Sn])=0.20 to 0.50.

4. The oxide sintered body according to claim 1, wherein, when a total amount of metal elements contained in the oxide sintered body is set to 1:
M2 metal is a metal comprising containing at least In or Ga of the M metals;
[Zn], [Sn], and [M2 metal] are contents (atomic %) of Zn, Sn, and M2 metal of all the metal elements, respectively; and
a ratio of [M2 metal] to [Zn]+[Sn]+[M2 metal], a ratio of [Zn] to [Zn]+[Sn], and a ratio of [Sn] to [Zn]+[Sn] respectively satisfy the following formulas:
[M2 metal]/([Zn]+[Sn]+[M2 metal])=0.10 to 0.30;
[Zn]/([Zn]+[Sn])=0.50 to 0.80;
and
[Sn]/([Zn]+[Sn])=0.20 to 0.50.

5. The oxide sintered body according to claim 1, wherein the oxide sintered body has a relative density of 90% or more, and a specific resistance of 0.1 Ω·cm or less.

6. A sputtering target obtained from the oxide sintered body according to claim 1, wherein the sputtering target has a Vickers hardness of 400 Hv or higher.

7. The sputtering target according to claim 6, wherein, when the Vickers hardness of the sputtering target in a thickness direction from a sputtering surface is approximated by Gaussian distribution, a distribution coefficient σ of the hardness is 30 or less.

8. The sputtering target according to claim 6, wherein, when a total amount of metal elements contained in the sputtering target is set to 1:
M1 metal is at least one metal element selected from the group consisting of Al, Hf, Ni, Si, and Ta of the M metals;
[Zn], [Sn], and [M1 metal] are contents (atomic %) of Zn, Sn, and M1 metal of all the metal elements, respectively; and
a ratio of [M1 metal] to [Zn]+[Sn]+[M1 metal], a ratio of [Zn] to [Zn]+[Sn], and a ratio of [Sn] to [Zn]+[Sn] respectively satisfy the following formulas:
[M1 metal]/([Zn]+[Sn]+[M1 metal])=0.01 to 0.30;
[Zn]/([Zn]+[Sn])=0.50 to 0.80;
and
[Sn]/([Zn]+[Sn])=0.20 to 0.50.

9. The sputtering target according to claim 6, wherein, when a total amount of metal elements contained in the sputtering target is set to 1:
M metal is a metal containing at least In or Ga of the M metals;
[Zn], [Sn], and [M2 metal] are contents (atomic %) of Zn, Sn, and M2 metal of all the metal elements, respectively; and
a ratio of [M2 metal] to [Zn]+[Sn]+[M2 metal], a ratio of [Zn] to [Zn]+[Sn], and a ratio of [Sn] to [Zn]+[Sn] respectively satisfy the following formulas:
[M2 metal]/([Zn]+[Sn]+[M2 metal])=0.10 to 0.30;
[Zn]/([Zn]+[Sn])=0.50 to 0.80;
and
[Sn]/([Zn]+[Sn])=0.20 to 0.50.

10. The sputtering target according to claim 6, wherein the sputtering target has a relative density of 90% or more, and a specific resistance of 0.1 Ω·cm or less.

11. The oxide sintered body according to claim 2, wherein, when a total amount of metal elements contained in the oxide sintered body is set to 1:
M1 metal is at least one metal element selected from the group consisting of Al, Hf, Ni, Si, and Ta of the M metals;
[Zn], [Sn], and [M1 metal] are contents (atomic %) of Zn, Sn, and M1 metal of all the metal elements, respectively; and
a ratio of [M1 metal] to [Zn]+[Sn]+[M1 metal], a ratio of [Zn] to [Zn]+[Sn], and a ratio of [Sn] to [Zn]+[Sn] respectively satisfy the following formulas:
[M1 metal]/([Zn]+[Sn]+[M1 metal])=0.01 to 0.30;
[Zn]/([Zn]+[Sn])=0.50 to 0.80;
and
[Sn]/([Zn]+[Sn])=0.20 to 0.50.

12. The oxide sintered body according to claim 2, wherein, when a total amount of metal elements contained in the oxide sintered body is set to 1:
M2 metal is a metal comprising at least In or Ga of the M metals;
[Zn], [Sn], and [M2 metal] are contents (atomic %) of Zn, Sn, and M2 metal of all the metal elements, respectively; and
a ratio of [M2 metal] to [Zn]+[Sn]+[M2 metal], a ratio of [Zn] to [Zn]+[Sn], and a ratio of [Sn] to [Zn]+[Sn] respectively satisfy the following formulas:
[M2 metal]/([Zn]+[Sn]+[M2 metal])=0.10 to 0.30;
[Zn]/([Zn]+[Sn])=0.50 to 0.80;
and
[Sn]/([Zn]+[Sn])=0.20 to 0.50.

13. The sputtering target according to claim 7, wherein, when a total amount of metal elements contained in the sputtering target is set to 1:
M1 metal is at least one metal element selected from the group consisting of Al, Hf, Ni, Si, and Ta of the M metals;
[Zn], [Sn], and [M1 metal] are contents (atomic %) of Zn, Sn, and M1 metal of all the metal elements, respectively; and
a ratio of [M1 metal] to [Zn]+[Sn]+[M1 metal], a ratio of [Zn] to [Zn]+[Sn], and a ratio of [Sn] to [Zn]+[Sn] respectively satisfy the following formulas:
[M1 metal]/([Zn]+[Sn]+[M1 metal])=0.01 to 0.30;
[Zn]/([Zn]+[Sn])=0.50 to 0.80;
and
[Sn]/([Zn]+[Sn])=0.20 to 0.50.

14. The sputtering target according to claim 7, wherein, when a total amount of metal elements contained in the sputtering target is set to 1:
M metal is a metal containing at least In or Ga of the M metals;
[Zn], [Sn], and [M2 metal] are contents (atomic %) of Zn, Sn, and M2 metal of all the metal elements, respectively; and
a ratio of [M2 metal] to [Zn]+[Sn]+[M2 metal], a ratio of [Zn] to [Zn]+[Sn], and a ratio of [Sn] to [Zn]+[Sn] respectively satisfy the following formulas:
[M2 metal]/([Zn]+[Sn]+[M2 metal])=0.10 to 0.30;
[Zn]/([Zn]+[Sn])=0.50 to 0.80;
and
[Sn]/([Zn]+[Sn])=0.20 to 0.50.
